(19) United States
(12) Patent Application Publication
(10) Pub. No.: US 2007/0232033 A1
(43) Pub. Date: Oct. 4, 2007

(54) METHOD FOR FORMING ULTRA-SHALLOW HIGH QUALITY JUNCTIONS BY A COMBINATION OF SOLID PHASE EPITAXY AND LASER ANNEALING

(76) Inventors: Karsten Wieczorek, Dresden (DE); Thorsten Kammler, Ottendorf-Okrilla (DE); Thomas Feudel, Radebeul (DE); Martin Gerhardt, Dresden (DE)

Correspondence Address: J. Mike Amerson;Williams, Morgan & Amerson, P.C., Suite 1100, 10333 Richmond, Houston, TX, 77042, US

(21) Appl. No.: 11/562,445

(22) Filed: Nov. 22, 2006

(30) Foreign Application Priority Data
Mar. 31, 2006 (DE) 10 2006 015 086.4

(51) Int. Cl. H01L 21/36

(52) U.S. Cl. 438/482; 438/506; 438/486

(57) ABSTRACT

By using a combination of solid phase epitaxy re-growth and laser annealing, the present invention provides a low thermal budget method which allows the crystal lattice of a semiconductor surface to recover after the doping by ion implantation. The low thermal budget limits the out-diffusion of the dopants ions, thus avoiding the enlargement of the doped source/drain regions. Therefore, the method is suited, for instance, for the fabrication of ultra-shallow source/drain regions in MOS transistors elements. The method according to the present invention comprises a first pre-amorphization process in order to limit channeling effects, a doping process by ion implantation and a re-crystallization by solid phase epitaxy, followed by laser annealing.

### BACKGROUND OF THE INVENTION

1. Field of the Invention

Generally, the present invention relates to the formation of integrated circuits, and, more particularly, to the formation of ultra-shallow junctions in semiconductor components.

2. Description of the Related Art

The fabrication of integrated circuits requires the formation of a large number of circuit elements on a given chip area according to a specified circuit layout. Generally, a plurality of process technologies are currently practiced, wherein, for complex circuitry, such as microprocessors, storage chips and the like, CMOS technology is currently one of the most promising approaches, due to the superior characteristics in view of operating speed and/or power consumption and/or cost efficiency. During the fabrication of complex integrated circuits using CMOS technology, millions of transistors, i.e., N-channel transistors and P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely doped channel region disposed between the drain region and the source regions.

The conductivity of the channel region is a dominant factor in determining the performance of MOS transistors. Thus, the reduction of the channel length, and associated therewith the reduction of the channel resistivity, renders the channel length an important design criterion for accomplishing an increase in the operating speed of the integrated circuits.

The continuing shrinkage of the transistor dimensions, however, involves a plurality of issues associated therewith that have to be addressed so as to not unduly offset the advantages obtained by steadily decreasing the channel length of MOS transistors. As transistor lateral dimensions are reduced to achieve higher speed performance and higher density of functional components on a die, the junction depths and doping profiles are also restricted to shallower locations. This scaling down of the junction depth has presently resulted in ultra-shallow junctions, having a depth of a few tens of nanometers and even less.

Therefore, highly sophisticated dopant profiles, in the vertical direction as well as in the lateral direction, are required in the drain and source regions in order to provide low sheet and contact resistivity in combination with a desired channel controllability. In particular, the vertical location of the PN junctions with respect to the gate insulation layer also represents a critical design criterion in view of leakage current control, since reducing the channel length may usually also require reducing the depth of the drain and source regions with respect to the interface formed by the gate insulation layer and the channel region, thereby requiring sophisticated doping techniques.

The doping can be done by diffusion and/or by implantation. Commonly, ion implantation is the preferred method for introducing dopants into specified device regions due to the ability to center the impurities around a desired depth and to relatively precisely control the number of dopant atoms implanted into substrates with a repeatability and uniformity of better than ±1%. Moreover, impurities that are introduced by ion implantation have a significantly lower lateral distribution when compared to conventional dopant diffusion processes. Since ion implantation is typically a room temperature process, the lateral profiling of a doped region may, in many cases, be conveniently achieved by providing a correspondingly patterned photoresist mask layer. These characteristics may render ion implantation currently, and in the near future, the preferred technique to produce doped regions in a semiconductor device.

In order to have good electrical properties and a low sheet resistivity R,, it is important that the junction regions have a good crystalline structure with a low defect density and a high integrity. This is also crucial in order to allow subsequent selective growth processes on these regions. Moreover, for an enhanced diode function of the junction, it is desirable to have a sharp and abrupt interface between the two differently doped regions. This holds especially true for the extension regions since they are particularly sensible parts of the junction due to their low depth and close proximity to the channel region.

In the following, a description will be given with reference to FIGS. 1a-1c of a typical doping process through ion implantation for a semiconductor substrate according to the state of art.

FIG. 1a schematically shows a semiconductor substrate 100, which could be an N-predoped or a P-predoped semiconductor. In order to obtain a junction in the substrate 100, the surface of the substrate is exposed to an ion beam 101, which, for instance, can be made of boron ions in order to generate a P-doped layer or phosphorous for an N-doped layer. The ions are accelerated and they penetrate into the substrate. The impact of energetic ions, however, leads to damage of the crystal lattice of the substrate. Ions lose energy through collision with substrate atoms. In these collisions, substrate atoms may be pushed out of their positions in the crystal lattice, such that lattice defects like vacancies and interstitials are created. The exposure to the ion beam damages and generates distortion in the crystal lattice; however, it does not typically cause the amorphization of the substrate.

FIG. 1b schematically shows the formation of a doped layer 103 in the upper part of the substrate 100 as a result of the exposure to the ion beam 101. In the figure, the high density of defects 104 caused by the ion implantation is also shown. Additionally, after ion implantation, the deposited dopants are not electrically active because they are sitting in interstitial sites instead of being incorporated into the crystal lattice of the substrate material. Beneath the layer 102 is a region of the layer 100, which has not been amorphized by the ion beam, but may contain a large number of defects 103 generated by the ions.

Therefore, ion implantation is typically followed by annealing, which substantially repairs the substrate damages and activates the dopants. Frequently this is done by rapid thermal annealing (RTA), where the substrate is exposed to high temperature for a short time. Thus, interface regions with low density of defects and dopant atoms sitting on sites in the crystal lattice of the substrate material are obtained. FIG. 1c schematically shows the substrate after the annealing process, which has sensibly reduced the density of defects in the substrate.

The implantation process has been generally described here for a substrate, but the same process can be applied to the fabrication of the source/drain regions in MOS transistors. The formation of the source/drain regions in MOS transistors can eventually include the formation of halo regions and extension regions, which are also obtained by standard implantation techniques, similarly to the process described above. During the fabrication of the source/drain regions, a pre-amorphization process can also be employed in order to avoid ion channeling effects.

The annealing is a problematic process and it can produce undesired effects. Both the repair of lattice defects and the diffusion of dopant atoms in the substrate are thermally activated processes, the rate of which increases with temperature. Therefore, annealing also leads to an undesirable broadening of the distribution of dopant atoms in the substrate induced by dopant diffusion. If the substrate is exposed to temperature T for a time t, dopant atoms diffuse over a typical distance:

d=\sqrt{2D(T)·t} (1)

which is denoted as thermal budget. Here, D(T) is the diffusion constant of dopant atoms at temperature T. Since the diffusion constant of dopant atoms increases with temperature, the thermal budget increases as the annealing temperature T and the duration t of the annealing process increase. If the size of field effect transistors is reduced, the thermal budget which can be tolerated is reduced since, in smaller structures, only dopant diffusion over a shorter distance can be tolerated. This problem is of particular relevance for dopants with a high diffusion coefficient as, for instance, boron. This, in turn, restricts the possibility to heal lattice damage induced by ion implantation. Thus, the annealing process is always a compromise between out-diffusion and defect elimination. In general, a certain number of defects are still present in the substrate even after the thermal annealing as shown in FIG. 1c.

In advanced RTA techniques, the substrate is exposed to a flash annealing using lamp arrays. Here the substrate is exposed to one or more bursts of radiation including a plurality of different wavelengths of a duration of 0.1 to several microseconds. Even if this method provides an efficient dopant activation, it still suffers from a relatively high thermal budget, when lattice defects are also to be significantly reduced by this technique.

For these reasons, the mentioned RTA techniques may not be suitable for highly scaled devices, such as sub-40 nm CMOS devices.

In the field of annealing techniques, laser annealing is emerging as a new technique. Here, after the ion implantation, the substrate is exposed to laser radiation with a specified wavelength in order to activate the dopant atoms. This method provides a very good activation of the dopants and, due to the very short time of exposure, it has low thermal budget. Nevertheless, laser annealing presents the problem that the post-annealing density of implant-induced lattice defects remains relatively high and thus the quality of the junction is poor.

Concluding, at the present stage, there is a need for a method which allows a high crystal quality and activation of the implanted regions, having a low thermal budget in order to avoid out-diffusion and allow the formation of ultra-shallow junctions.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention relates to a technique for forming an ultra-shallow junction in a crystalline semiconductor substrate based on a combination of solid phase epitaxy and laser annealing, which allows a high quality lattice structure of the junction region and a good activation of the doping material. Furthermore, the whole process is characterized by a low thermal budget, which avoids or at least significantly reduces the out-diffusion of implanted dopant ions.

According to one illustrative embodiment of the present invention, a method for forming a semiconductor junction comprises forming a substantially amorphous layer above a substantially crystalline semiconductor layer formed above a substrate, followed by forming a doped layer in at least one of the substantially amorphous layer or the substantially crystalline semiconductor layer. The method further comprises re-growing the substantially amorphous layer and activating dopants in the doped layer by a pulsed radiation anneal process.

According to another illustrative embodiment of the present invention, a method comprises forming at least a portion of source/drain regions in a semiconductor layer formed above a substrate and re-crystallizing the source/drain regions by thermal treating the substrate. The method further comprises activating dopants in the portions of source/drain regions by laser annealing the source/drain regions.

### BRIEF DESCRIPTION OF THE DRAWINGS

The invention may be understood by reference to the following description taken in conjunction with the accompanying drawings, in which like reference numerals identify like elements, and in which:

FIGS. 1a-1c schematically show the fabrication of a junction in a crystalline semiconductor substrate comprising a doping process by ion implantation followed by rapid thermal annealing (RTA) according to prior art techniques;

FIGS. 2a-2d schematically show the fabrication of a junction in a crystalline semiconductor substrate, which includes a pre-amorphization, a doping process by ion implantation and a re-growth process by solid phase epitaxy (SPE) followed by laser annealing, according to an illustrative embodiment of the present invention;

FIG. 3 schematically shows the fabrication process of a multi-layer structure comprising doped layers with different electrical properties according to an illustrative embodiment of the present invention including a pre-amorphization step and a re-growth process by solid phase epitaxy and the activation of the doping material by laser Annealing; and

FIGS. 4a-4e schematically show the fabrication process of ultra-shallow junctions for the source/drain regions in a MOS transistor element including a pre-amorphization, doping by ion implantation, re-growth of the implanted regions by solid phase epitaxy and activation of the doping material by laser annealing according to illustrative embodiments.

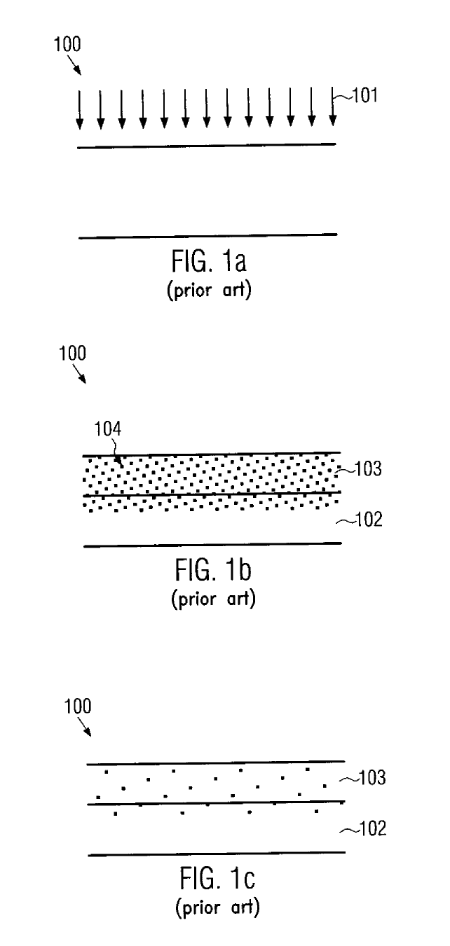

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present invention is directed to a technique that enables the formation of high quality ultra-shallow junctions between differently doped crystalline semiconductor regions. The method can be applied, for instance, to the formation of the source/drain regions in MOS transistors, in particular for problematic parts like the extension regions, which might be few tens of nanometers deep or less. For this purpose, a combination of solid phase epitaxy, i.e., a re-growth at moderately high temperatures substantially without liquefying the material, and laser annealing, i.e., using laser radiation for heating the material, may be used, which provides a high quality re-crystallization of the junction regions and a good activation of the introduced doping material. In one embodiment, a first pre-amorphization of a substrate by implantation of heavy ions is performed, which generates a substantially amorphous layer in the upper part of a substrate or semiconductor layer. The substantially amorphous layer may then be doped by ion implantation with an appropriate energy, which may be an ultra-low energy for advanced applications, thus forming a shallow doped layer and avoiding or reducing channeling effects. After the doping process, the amorphous layer may be brought to a temperature between approximately 600-800° C. in order to initiate the re-crystallization process in the substantially amorphous material. The substrate re-crystallizes in this way by solid phase epitaxy. This technique ensures the formation of a high quality lattice structure of the junction region with a sharp interface and a good activation of the doping atoms. Consequently, a low thermal budget is achieved.

This avoids the extension of the doped region after the implantation, because the temperatures employed are not high enough to cause significant out-diffusion processes of the doping ions. Therefore, the method according to the present invention allows the formation of sharp interfaces for junctions with a depth on the order of tens of nanometers and even less. Moreover, in some illustrative embodiments of the present invention, the method can be applied to form structures with more than one doped layer having different electrical properties.

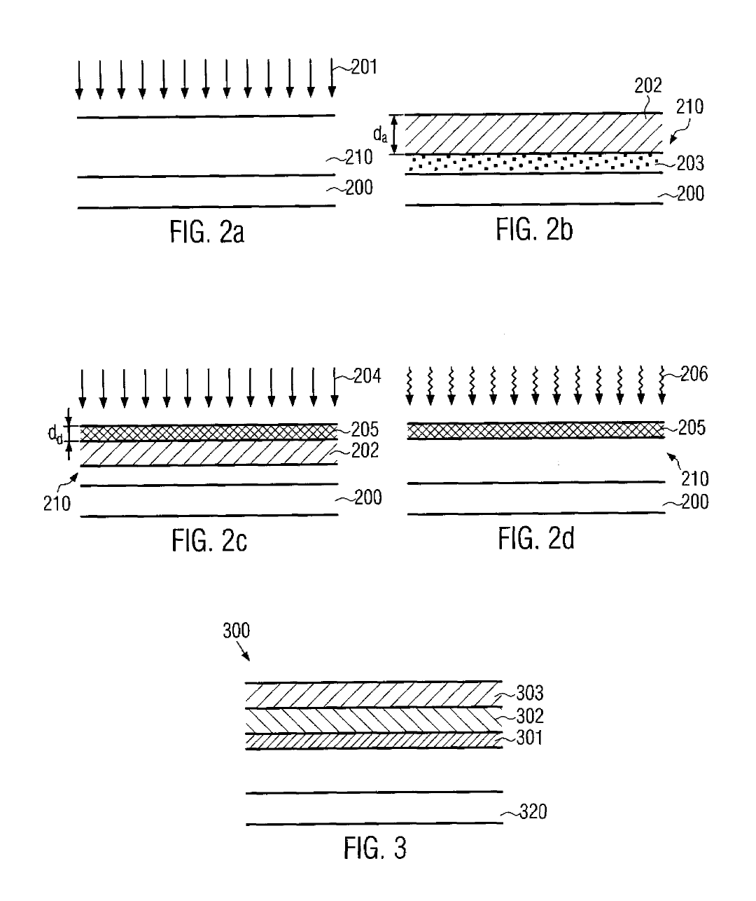

In the following, further illustrative embodiments, according to the present invention, will be described in more detail. In particular, a method for forming a semiconductor junction according to the present invention will be illustrated with reference to FIGS. 2a-2d.

FIG. 2a schematically illustrates a crystalline semiconductor layer 210 formed above a substrate 200, which, for instance, could be N-predoped. The layer 2 10 is exposed to a pre-amorphization process, which may comprise an ion implantation 201. In an illustrative embodiment, the ion beam of the implantation 201 consists of argon ions, but it could be made of other noble gas ions, like xenon or other suitable elements for the amorphization of a portion of the layer 210. The pre-amorphization process 201 may avoid or reduce the channeling effects during a subsequent doping process and also enhance the efficiency of the solid phase epitaxy process.

FIG. 2b schematically illustrates the substrate 200 after the amorphization process, where a substantially completely amorphous layer 202 has been formed in the layer 2 1 0 The thickness of the amorphous layer 202 is dₐ. Beneath the layer 202 is a region of the layer 210, which has not been amorphized by the ion beam, but may contain a large number of defects 203 generated by the ions.

FIG. 2c schematically illustrates the substrate 200, which is exposed to a subsequent implantation 204 of doping material. The ion beam of the implantation 204 may comprise boron, arsenic or phosphorus or any other element suitable for doping the layer 202 as required. The doping process 204 generates a doped layer 205, for instance at the top of the layer 210. This doped layer 205 has a depth which is d_{d}. In an illustrative embodiment according to the present invention, the depth d_{d} of the doped layer 205 is less than the depth of the amorphous layer 202, so that the doped layer 205 is entirely included in the amorphous layer 202. In an illustrative embodiment of the present invention, the dopant implantation 204 is done at ultra-low energy, i.e., at 1 keV or less, depending on the dopant species and the desired junction depth.

After the dopant implantation 204, the substrate 200 undergoes a re-growth process. The substrate 200 is exposed to a thermal treatment at low temperature in order to re-crystallize the amorphous layer 202. In an illustrative embodiment of the present invention, the temperature is in the range of approximately 600-800° C. The crystallization of amorphous material on a crystalline substrate represents a solid phase epitaxy (SPE) process. During SPE, the amorphous/crystalline interface moves towards the surface at a fixed velocity that depends on temperature, doping and crystal orientation. The activation energy for SPE in silicon is 2.3 eV. If the layer 202 is not amorphous but the lattice structure has been damaged by the ion implantation, the lattice repair occurs by generation and diffusion of point defects. This process has an activation energy of about 5 eV. It is therefore easier in many cases to repair a fully amorphous layer than a partially damaged one. This re-growth process results in a high quality re-crystallization of the lattice structure and it has the advantage that out-diffusion of dopant atoms is avoided or reduced due to the low temperature required for the process. SPE has the disadvantage that it provides only a poor dopant activation. For this reason, the substrate is afterward exposed to a radiation-based anneal process including short radiation pulses. In one embodiment, the pulsed radiation anneal process comprises laser annealing. The lattice defects 203 generated by ion implantation in the crystalline substrate can eventually still be present after the SPE process. These defects are far away from the PN junction anyway, which is entirely made in the amorphous layer 202, thus the presence of these defects would not influence the electrical properties of the junction region.

FIG. 2d schematically illustrates the substrate 200 after the SPE process when it is exposed to a laser annealing 206, in order to activate the dopant atoms implanted in the layer 205. After the re-crystallization by solid phase epitaxy, a large number of doping atoms occupies interstitial position within the lattice structure and thus they are electrically inactive. The laser annealing induces very high temperatures with a duration in the micro-ns range, which produces an excellent activation, while keeping the thermal budget of the process low. The laser radiation provides enough energy to the doping atoms which occupy interstitial positions to reach a lattice site, thus making them electrically active. The radiation time is so short that the dopant atoms do not get enough energy to diffuse inside the substrate, causing an undesired expansion of the doped regions. Therefore, laser annealing provides efficient activation of the dopants atoms, while avoiding or at least suppressing out-diffusion effects.

In an illustrative embodiment of the present invention, the doped layer 205 could extend over the whole amorphous layer 202 or even beyond it, and not only over the upper part of it as described in a previous embodiment, when a steep dopant gradient is required at extremely shallow layer portions only, such as extension regions and the like. Hence, lattice defects caused by the amorphization implant may not affect the deeper source/drain regions.

In a further illustrative embodiment of the present invention, the substrate could be first exposed to the laser annealing and afterward undergoes the SPE process. In this way, the laser annealing may reduce defects from the crystalline part of the layer 210, which is beneath the amorphous layer 202. The SPE would than take place based on a crystal template with a good quality which allows a better re-growth of the amorphous layer 202.

In a further embodiment according to the present invention, as shown schematically in FIG. 3, a structure 300 with more than one layer can be formed, wherein the layers have different electrical properties. The different layers are vertically disposed one over the other above a substrate 320. With ion implantation, it is possible to introduce dopants at a desired depth in the substrate. Therefore, after a first pre-amorphization process, a first layer 301 with a desired doping in the lower part of the amorphous layer may be formed, then this first doped layer may be re-grown by SPE and subsequently exposed to laser annealing. Afterwards, a second layer 302 with a different doping may be formed on the top of the first one and the steps of ion implantation, solid phase epitaxy and laser annealing may be repeated. All the layers have a sharp/abrupt interface, high lattice quality and good activation of the dopants. This method for the formation of multi-layer structures could be applied in source/drain regions requiring sophisticated vertical dopant profiles. According to an alternative embodiment of the present invention, the SPE step and the laser step could be performed only once at the end of the process, i.e. after all the layers with different doping have been implanted.

Summarizing, the method described combines solid phase epitaxy and laser annealing and it forms sharp/abrupt interfaces between regions doped by ion implantation, providing a high quality lattice structure and a good dopant activation. The method has the advantage that the thermal budget of the process is kept low and thus out-diffusion is avoided or significantly reduced.

The method described with reference to FIG. 2a-2d can be applied to the fabrication of MOS transistor elements, in particular to the formation of ultra-shallow junctions in MOS transistors.

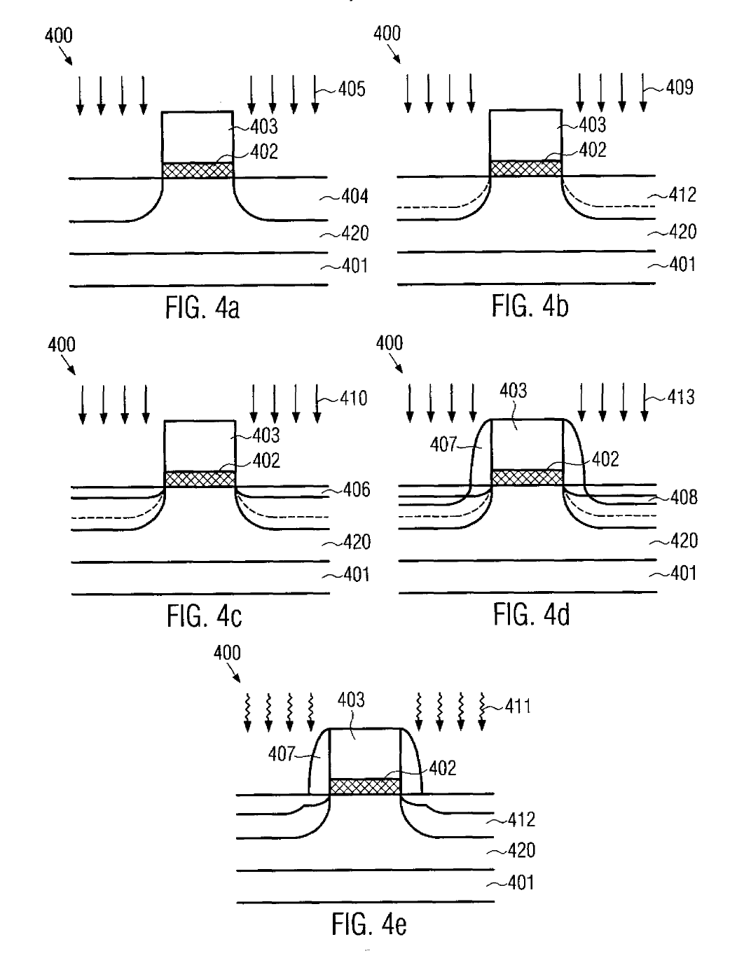

An illustrative embodiment of the present invention will be described in detail with reference to FIGS. 4a-4e illustrating a typical process flow for the formation of high quality ultra-shallow junctions in MOS transistors.

FIG. 4a schematically shows a transistor element 400, where, following the formation of a gate insulation layer 402 and an overlaying gate electrode 403 according to well-known lithography and etching techniques, amorphous regions 404 are formed during a pre-amorphization step by ion implantation 405. To this end, a semiconductor layer 420 formed above a substrate 401 is exposed to the ion beam 405 and heavy ions such as, for example, argon, xenon or other suitable elements, are implanted into the layer 420. The amorphization is done in order to reduce the channeling during the subsequent implantation of doping material and to allow re-growth of the doped regions.

In a next step, as depicted in FIG. 4b, halo regions 412 of the transistor element 400 are formed. In particular, a further ion implantation step is carried out during which the transistor 400 is exposed to an ion beam 409. The dopant concentration in the regions 412, as well as the implant energy of the dopants, are selected depending on the type of transistor to be formed above the substrate 401. The dopant material implanted during such a process is of the same type as the dopant used for doping the substrate. That is, the halo implants for NMOS and PMOS devices are performed using a P-type and an N-type dopant material, respectively. In a sense, the halo implants reinforce the dopants in the layer 420.

In FIG. 4c is shown schematically the formation of the source/drain extension regions 406. This is made exposing the transistor element 400 to the ion beam 410. This third ion implantation step is performed with N-type and P-type dopant materials for NMOS and PMOS devices, respectively.

During a subsequent step, the source/drain regions 408 of the transistor 400 are completed as depicted in FIG. 4d. In particular, dielectric sidewalls spacers 407 are formed on the sidewalls of the polysilicon gate 403 according to well-known techniques, and a further implantation step 413 is carried out for implanting dopants into those regions of the substrate not covered by the gate electrode 403 and the sidewall spacers 407. At the end of the implantation step 413, the source/drain regions 408 are formed to exhibit the desired dopant concentration. For NMOS and PMOS type devices, this implantation step 413 is performed using an N-type and a P-type dopant material, respectively.

In a next step, the implanted regions, including the halo, extension and deep source/drain regions, which have an amorphous structure are exposed to thermal treatment, which re-crystallizes the amorphous regions. This is done by heating the substrate 401 at a temperature between approximately 600-800° C., thus a re-growth by solid phase epitaxy takes place.

FIG. 4e schematically shows the transistor element 400 after the re-crystallization by solid phase epitaxy of the amorphous regions. Further, in order to activate the different doped layers which form the source/drain regions, the substrate is exposed to a laser annealing 411 which provides a very good activation, as is previously described.

In a further illustrative embodiment according to the present invention for the fabrication of MOS transistors, the re-growth by solid phase epitaxy and the laser annealing treatment could be done after every implantation process of dopant material, i.e., after the halo region implantation, the extension region implantation and the source/drain implantation, instead of only at the end of all the implantation processes as described in a previous embodiment. This sequence of steps can provide, under given conditions, an even more enhanced quality of the lattice structure.

Concluding, the present invention relates to a combination of solid phase epitaxy and laser annealing for ultra-shallow high quality junctions. The invention provides shallow junctions with a low sheet resistance (Rₛ) with excellent junction integrity by yielding excellent crystalline re-growth. Continuous device scaling requires constant junction scaling at decreasing sheet resistances. Simultaneously, excellent crystalline re-growth of the distorted lattice is required for both selective epitaxy and improved junction integrity. In fact, selective epitaxy is possible only on a surface with a very low defects density, because defects can severely compromise the growth process by selective epitaxy. This selective growth process is typically applied for the formation of embedded and raised source/drain regions, which are used, for example, in order to obtain a strained channel region in a transistor element. The method according to the present invention allows a high quality lattice structure and thus the subsequent selective epitaxy in case of embedded or raised source/drain regions. This invention combines solid phase epitaxy and subsequent laser annealing to accomplish this objective. State-of-the-art implant annealing/activation is accomplished by standard RTA processing. However, even advanced RTA equipment using lamp arrays suffer from relatively high thermal budget. This results in a substantial out-diffusion of high-diffusivity dopants (e.g., boron) and this imposes a scaling limitation to sub-40 nm CMOS devices. Recently, laser annealing is emerging as an alternative annealing technique, but this approach results in relatively high post-annealing density of implant-induced lattice defects and thus poor junction. This invention combines pre-amorphization with subsequent dopant implantation, SPE and laser annealing to accomplish ultra-shallow junctions, extremely high activation (and thus low Rₛ) and excellent lattice quality of the resulting junction. In one illustrative example, the respective crystal, e.g., silicon layer, is first amorphized so as to avoid tunneling. Then, the dopant is implanted at ultra-low energy, e.g., sub-1 keV range. The amorphized, doped layer is then re-crystallized at low temperatures (600-800° C.). This solid phase epitaxy results in high-quality re-growth of the lattice but generally yields only poor dopant activation. Due to low temperature, dopant out-diffusion may be effectively avoided or at least be significantly reduced. Then, the dopants are activated by laser annealing. The laser induces very high temperatures in the micro-ns range, resulting in excellent activation without any measurable out-diffusion.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method for forming a semiconductor junction, comprising:
forming a substantially amorphous layer above a substantially crystalline semiconductor layer formed above a substrate;
forming a doped layer in at least one of said substantially amorphous layer and said substantially crystalline semiconductor layer;
re-growing said substantially amorphous layer; and
activating dopants in said doped layer by a pulsed radiation anneal process.

2. The method of claim 1, wherein said pulsed radiation annealing process comprises using laser radiation.

3. The method of claim 1, wherein re-growing said substantially amorphous layer comprises heating said substrate without liquefying portions of said substrate.

4. The method of claim 1, wherein re-growing said substantially amorphous layer comprises thermal treating said substrate at a temperature ranging from approximately 600-800° C.

5. The method of claim 1, wherein said substantially amorphous layer is partially formed by performing an ion implantation process.

6. The method of claim 1, wherein said substantially crystalline semiconductor layer is a silicon layer.

7. The method of claim 1, wherein said doped layer is formed by performing an ion implantation process.

8. The method of claim 7, wherein said ion implantation process is performed at an energy of approximately 1 keV or less.

9. The method of claim 1, wherein said pulsed radiation anneal process comprises generating one or more radiation pulses with a duration in the range of approximately one nanosecond to several microseconds.

10. The method of claim 1, wherein said doped layer is formed so as to function as a shallow PN junction of a transistor device.

11. The method of claim 1, wherein said pulsed radiation anneal process is performed after re-growing said substantially amorphous layer.

12. The method of claim 1, wherein said pulsed radiation anneal process is performed prior to re-growing said substantially amorphous layer.

13. The method of claim 1, wherein said steps of forming a doped layer, re-growing said substantially amorphous layer and activating the dopant are repeated more than once during the whole process.

14. A method, comprising:
forming at least a portion of source/drain regions in a semiconductor layer formed above a substrate;
re-crystallizing said source/drain regions by thermal treating said substrate; and
activating dopants in said portions of source/drain regions by laser annealing said source/drain regions.

15. The method of claim 14, further comprising forming a substantially amorphous region in said semiconductor layer prior to forming said source/drain regions.

16. The method of claim 14, wherein re-crystallizing said source/drain regions comprises performing a solid phase epitaxy process.

17. The method of claim 15, wherein said substantially amorphous region is formed by ion implantation.

18. The method of claim 14, wherein said portion of said source/drain regions are the source/drain extension regions.

19. The method of claim 17, wherein said ion implantation is performed at an energy of approximately 1 keV or less.

20. The method of claim 14, wherein said re-crystallizing is performed at a temperature ranging from approximately 600-800° C.

21. The method of claim 16, wherein said solid phase epitaxy process is performed prior to said laser annealing.

22. The method of claim 16, wherein said solid phase epitaxy process is performed after said laser annealing.
